(19) United States
(12) Patent Application Publication
(10) Pub. No.: US 2008/0037224 A1
(43) Pub. Date: Feb. 14, 2008

(54) Heat sink

(75) Inventors: Chin-Ming Chen, Taoyuan Hsien (TW); Yu-Hung Huang, Taoyuan Hsien (TW); Alex Hsia, Taoyuan Hsien (TW); Tsung-Lin Chen, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/882,851

(22) Filed: Aug. 6, 2007

(30) Foreign Application Priority Data
Aug. 14, 2006 (TW) 95129721

(51) Int. Cl. H05K 7/20

(52) U.S. Cl. 361/717

(57) ABSTRACT

A heat sink has a heat-dissipating portion and a contact portion for contacting an electric device generating heat. The diameter of the contact portion is smaller than that of the heat-dissipating portion. The heat-dissipating portion has a plurality of fins. The contact portion is disposed on a bottom surface of the heat-dissipating and formed with the heat-dissipating portion as a single unitary member. The contact portion includes a first axial cross section and a second axial cross section. The first axial cross section is away from the heat-dissipating portion, and the second axial cross section is near the heat-dissipating portion. The diameter of the first axial cross section is larger than that of the second axial cross section.

### BACKGROUND OF THE INVENTION

1. Field of the Invention

The invention relates to a heat sink, and more particularly to a heat sink which can be manufactured and packaged automatically so that the manufacturing time, the need for manual labor and cost can be reduced.

2. Description of the Related Art

A central processing unit, CPU, is applied to process instructions and control operations in an electronic device. Continuous development of CPU speed has also resulted in continuously increasing operating temperature. A heat sink is typically installed on the CPU of the electronic device to dissipate heat.

A conventional heat sink includes a heat-dissipating portion and a contact portion. The contact portion is a shape of column and an axial edge of the contact portion is perpendicular to a bottom surface of the heat-dissipating portion. The column-shaped contact portion cannot be handled by robotic equipment in an automated procedure so that a conventional heat sink is transmitted and packaged by manual labor. Thus, the process is time-consuming, requires manual labor and increases cost.

In order to eliminate above disadvantages, another conventional heat sink provides a metal X clip disposed on the edge of the contact portion thereof so that the heat sink can be caught by a robot. The X clip is fixed on the contact portion by clipping or rivet jointing. The X clip is detachably installed on the heat sink and thus, installing X-clip on the heat sink increases the number of assembly steps and required equipment. Manual labor is required in the manufacturing process of the conventional heat sink for transmission and packaging. Thus, installing the X clip does not reduce time-consumption, manual labor, and manufacturing or material costs.

The X clip disposed on the edge of the contact portion of the heat sink increases heat resistance resulting in reduced efficiency when the heat sink dissipates heat generated by a electric device. Thus, the conventional heat sink does not reduce costs and manufacturing time via automatic production.

### BRIEF SUMMARY OF INVENTION

The invention provides a heat sink which can be manufactured and packaged automatically so that the need for manual labor, manufacturing time and cost can be reduced.

The invention provides a heat sink for reducing material costs.

An exemplary embodiment of a heat sink according to the present invention includes a heat-dissipating portion and a contact portion. The heat-dissipating portion includes a shape of column and a radial edge constituted by a plurality of fins. The contact portion is disposed on a bottom of the heat-dissipating portion. The contact portion is connected to an electric device generating heat, e.g. CPU. A diameter of the contact portion is less than that of the heat-dissipating portion. The contact portion and the heat-dissipating portion are a single unitary member. The contact portion includes at least a concave disposed on the radial edge of the contact portion.

Another exemplary embodiment of the heat sink according to the present invention includes a heat-dissipating portion and a contact portion. The heat-dissipating portion includes a shape of column and a radial edge constituted by a plurality of fins. The contact portion is disposed on a bottom of the heat-dissipating portion. A diameter of the contact portion is less than that of the heat-dissipating portion. The heat-dissipating portion includes a radial edge constituted by a plurality of fins. The contact portion is disposed on a bottom of the heat-dissipating portion. The contact portion and the heat-dissipating portion are a single unitary member. The contact portion for connecting to an electric device generating heat includes at least one groove located on the periphery of the heat-dissipating portion.

The heat sink of the present invention includes a groove formed on the periphery of the heat-dissipating portion or a concave formed on the contact portion. In the manufacturing process, a robot grabs the groove or the concave of the heat sink to transmit and package. Thus, the heat sink is manufactured and packaged automatically so that the manual labor and the manufacturing time can be reduced.

Because the concave of the contact portion or the groove of the heat-dissipating portion is formed, the X clip is no need to install on the heat sink as in a conventional heat sink. Thus, the material costs can be reduced.

A detailed description is given in the following embodiments with reference to the accompanying drawings.

### BRIEF DESCRIPTION OF DRAWINGS

The present invention will become more fully understood from the subsequent detailed description and the accompanying drawings, which are given by way, of illustration only, and thus are not limitative of the present invention, and wherein:

FIG. 1 is a schematic view showing an embodiment of the heat sink of the present invention;

FIG. 2 is a lateral view of the heat sink shown in FIG. 1;

FIG. 3 is a lateral view showing another embodiment of the heat sink of the invention;

FIG. 4 is a lateral view showing another embodiment of the heat sink of the invention;

FIG. 5 is a lateral view showing another embodiment of the heat sink of the invention;

FIG. 6 is a lateral view showing another embodiment of the heat sink of the invention;

FIG. 7 is a lateral view showing another embodiment of the heat sink of the invention;

FIG. 8 is a schematic view showing another embodiment of the heat sink of the invention; and

FIG. 9 is a top view of the heat sink shown in FIG. 8.

### DETAILED DESCRIPTION OF INVENTION

The following description is of the best-contemplated mode for carrying out the invention. This description is made for the purpose of illustrating the general principles of the invention and should not be taken in a limiting sense. The scope of the invention is best determined by reference to the appended claims.

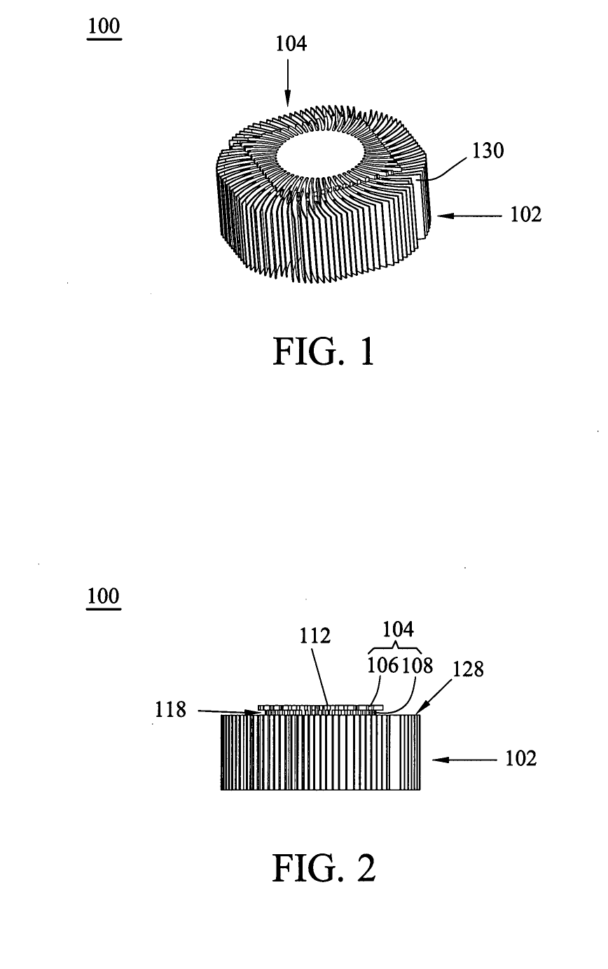

FIG. 1 is a schematic view showing an embodiment of a heat sink 100 of the invention. FIG. 2 is a lateral view of the heat sink 100 shown in FIG. 1. Referring to FIGS. 1 and 2, the heat sink 100 includes a heat-dissipating portion 102 and a contact portion 104. The heat-dissipating portion 102 and the contact portion 104 is a single and unitary member. As shown in FIG. 2, the contact portion 104 includes a contact surface 112 which can be connected to an electric device generating heat (not shown). An external diameter of the contact portion 104 is less than that of the heat-dissipating portion 102. The heat sink 100 can be made of, for example, copper, aluminum; gold, silver and alloys thereof.

The heat-dissipating portion 102 is a shape of column. The heat-dissipating portion 102 includes a radial edge constituted by a plurality of fins 130. The heat-dissipating portion 102 and the contact portion 104 can be coaxial. The shape of the cross section of the heat-dissipating portion 102 is the same as or different from the shape of the extended cross section of the contact portion 104.

The heat-dissipating portion 102 includes a bottom surface 128 and the contact portion 104 is disposed on the bottom surface 128. The shape or the size of the contact surface 112 connected to the contact portion 104 corresponds to the electric device generating heat.

The contact portion 104 includes a first portion 106 and a second portion 108. The area of the axial cross section of the first portion 106 is greater than that of the axial cross section of the second portion 108 so that a concave 118 is formed between the first portion 106 and hest-dissipating portion 102. A top view of the concave 118 can be polygon, bar, ring or curve shape. The first portion 106 is spaced apart by a distance from the heat-dissipating portion 102. The second portion 108 is near the heat-dissipating portion 102. The second portion 108 includes a top surface connected to the first portion 106 and a bottom surface connected to the heat-dissipating portion 102. Furthermore, the radial edge of the first portion 106 or the radial edge of the second portion 108 is constituted by the bottom of the fins 130.

The first portion 106 or the second portion 108 can be column, polygon, taper or trapezoid. The cross section of the first portion 106 or the second portion 108 can be circular, polygon, elliptic, approximately circular, regular or irregular. The shape of first portion 106 can be the same as the shape of second portion 108. In this embodiment, the first portion 106 and the second portion 108 are rectangles.

The heat sink of the invention includes the concave 118 formed on the contact portion 104. In the manufacturing process, a robot grabs the concave 118 of the heat sink 100 to transmit and package the heat sink so that the manual labor can be eliminated. The concave 118 is formed directly on the contact portion 104 and thus, installation of an accessory, e.g. X clip of the conventional heat sink, is not required and the cost of material for the heat sink is eliminated.

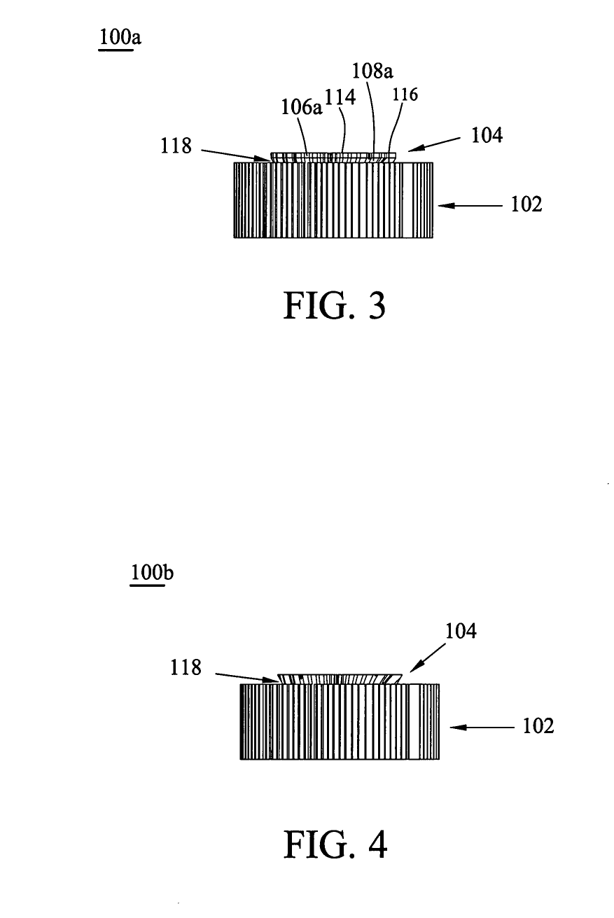

FIG. 3 is a lateral view of another embodiment of a heat sink 100a of the invention. In comparison with FIGS. 2 and 3, the difference is the edge of the second portion 106a of the heat sink 100a is inclined. The first portion 106a includes at least one first axial cross section 114 and the second portion 108a includes at least one second axial cross section 116. The first axial cross section 114 is spaced apart by a distance from the heat-dissipating portion 102 and the second axial cross section 116 is near the heat-dissipating portion 102 so that a concave 118a is formed. The first axial cross section 114 is larger than the second axial cross section 116. The shape of the first axial cross section 114 is the same shape as the second axial cross section 116 but is not limited to this.

The edge size of the first axial cross section 114 is greater than that of the second axial cross section 116. The first axial cross section 114 and the second axial cross section 116 further include one or over two corners. The corner size of the first axial cross section 114 is greater than that of the second axial cross section 116.

FIG. 4 is a lateral view of another embodiment of a heat sink 100b of the invention. In comparison with FIGS. 3 and 4, the difference is that the contact portion 104 is not divided into two parts. The area of the axial cross section of the contact portion 104 increases along a direction spaced apart the heat-dissipating portion 102, the edge of the contact portion 104 is inclined so that a concave 118b is formed.

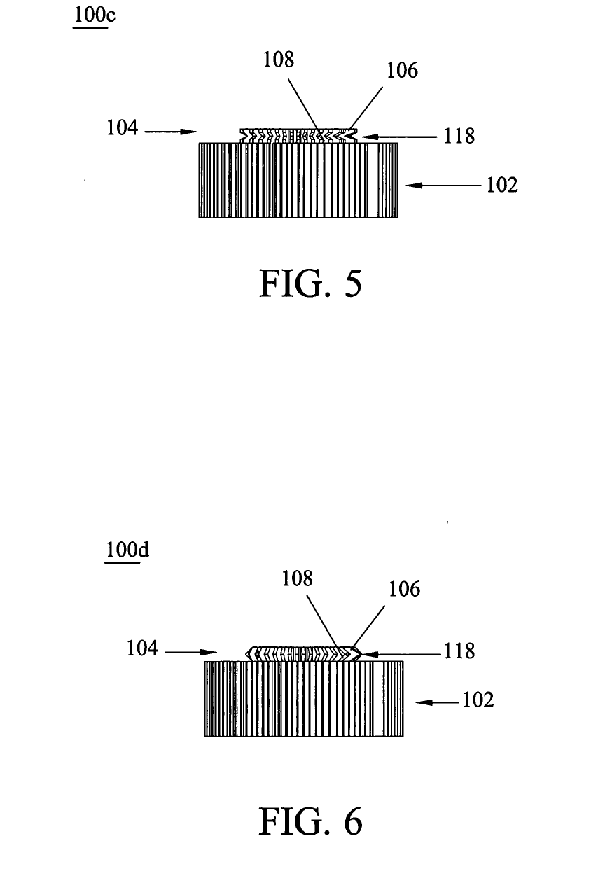

FIG. 5 is a lateral view of another embodiment of a heat sink 100c of the invention. In comparison with FIG. 4, the difference shown in FIG. 5 is that a V-shaped concave 118c is formed between the first portion 106 and the second portion 108 of the contact portion 104.

FIG. 6 is a lateral view of another embodiment of a heat sink 100d of the invention. In comparison with FIGS. 5 and 6, the difference is that the contact portion 104 is a diamond shape. As shown in FIG. 6, the area of the axial cross section of the second portion 108 increases along a direction away from the heat-dissipating portion 102. The area of the axial cross section of the first portion 106 decreases along a direction away from the heat-dissipating portion 102 so that a concave 118d is formed. On the contrary, the area of the axial cross section of the first portion 106 may increase along a direction away from the heat-dissipating portion 102. The area of the axial cross section of the second portion 108 may decrease along a direction away from the heat-dissipating portion 102. Otherwise, the areas of the axial cross sections of the first portion 106 and the second portion 108 simultaneously increases or decreases along a direction away from the heat-dissipating portion 102.

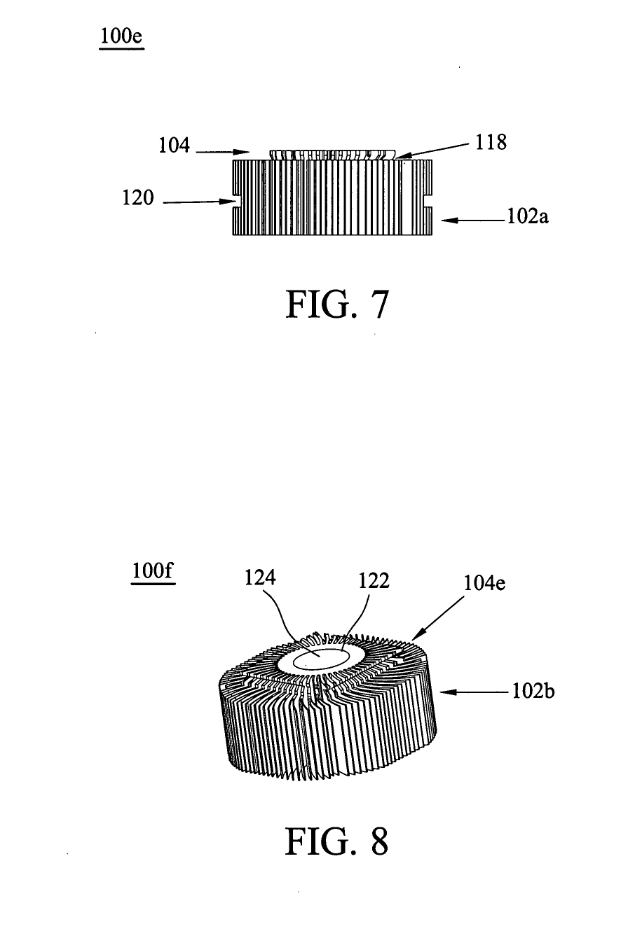

FIG. 7 is a lateral view of another embodiment of the heat sink 100e of the invention. In comparison with FIGS. 3 and 7, the difference is that the heat-dissipating portion 102a includes at least a groove 120. The groove 120 is located on the periphery of the heat-dissipating portion 102a. The groove 120 can be polygon, bar, ring or curve shape.

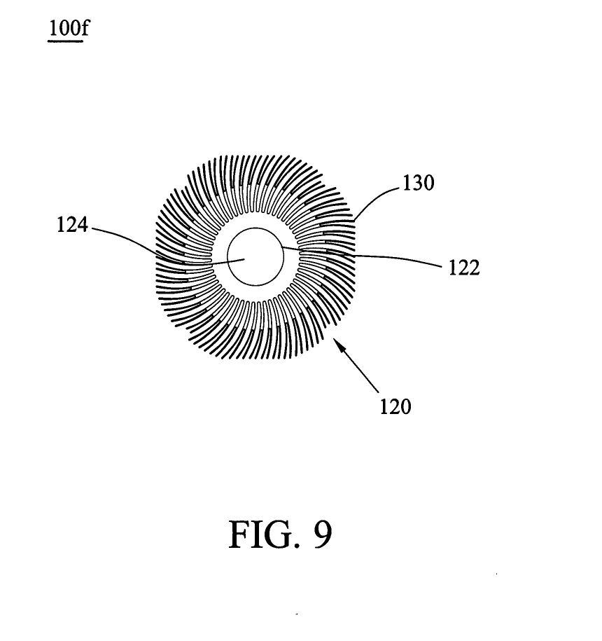

FIG. 8 is a schematic view of another embodiment of the heat sink 100f of the invention. FIG. 9 is a top view of the heat sink shown in FIG. 8. In comparison with FIGS. 1 to 7, the difference is that the heat sink 100f includes a through hole 122 and a thermally conducting member 124 disposed in the through hole 122. The through hole 122 is disposed in the middle of the heat-dissipating portion 102b and the contact portion 104e. The through hole 122 passes through the contact portion 104e and extends to the heat-dissipating portion 102b. The through hole 122 can be a shape of column, rhombus, polygon, taper or trapezoid shape. The thermally conducting member 124 is connected to the contact portion 104e and the electric device. The thermally conducting member 124 can be a shape corresponding to that of the through hole 122. The cross section of the thermally conducting member 124 can be a circular, polygon, elliptic, approximately circular, regular shaped or irregular shape. The thermally conducting member is made of copper, aluminum, gold, silver or alloys thereof.

In this embodiment, the material of the thermally conducting member 124 can be the same as or different from the material of the heat sink 100f. When the material of the thermally conducting member 124 is different from that of the heat sink 100f, the thermally conducting member 124 can be made of an expensive material with high thermal conductivity. The heat sink 100f can be made of an inexpensive material with lower thermal conductivity than material of the thermally conducting member 124. Thus, heat generated by the electric device is dissipated from the heat sink 100f, and cost is reduced.

The differences of the above-mentioned embodiments are used to apply to the heat sink simultaneously or selectively.

The heat sink of the invention includes a groove formed on the periphery of the heat-dissipating portion or a concave formed on the contact portion. In the manufacturing process, a robot grabs the groove or the concave of the heat sink to transmit and package the heat sink. Thus, the heat sink is manufactured and packaged automatically eliminating manual labor, and reducing manufacturing time and cost.

Furthermore, because the concave of the contact portion or the groove of the heat-dissipating portion is formed, the X clip is no need to install on the heat sink as in a conventional heat sink. Thus, the heat sink of the invention substantially reduces material costs.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A heat sink comprising:
a heat-dissipating portion having a plurality of fins; and
a contact portion having a diameter less than that of the heat-dissipating portion and disposed on heat-dissipating portion, wherein the contact portion and the heat-dissipating portion are a single unitary member, and the contact portion comprises a first axial cross section away from the heat-dissipating portion; and a second axial cross section closing with the heat-dissipating portion,
wherein the first axial cross section is larger the second axial section.

2. The heat sink as claimed in claim 1, wherein the contact portion comprises a first portion and a second portion, the second portion comprises a top surface and a bottom surface, both of which are respectively connected to the first portion and the heat-dissipating portion, the first axial cross section is located on the first portion, and the second axial cross section is located on the second portion.

3. The heat sink as claimed in claim 2, wherein the first portion or the second portion is constituted by the bottom of the fins.

4. The heat sink as claimed in claim 2, wherein an edge of the first portion or an edge of the second portion is inclined.

5. The heat sink as claimed in claim 2, wherein the axial cross section of the first portion or the second portion decreases along a direction away from the heat-dissipating portion, or the axial cross section of the first portion or the second portion increases along a direction away from the heat-dissipating portion.

6. The heat sink as claimed in claim 2, wherein there is a V-shaped concave formed between the first portion and the second portion.

7. The heat sink as claimed in claim 1, further comprising a through hole passing through the contact portion and extending to the heat-dissipating portion for allowing a thermally conducting member to be disposed in the through hole so that an electric device generating heat can be connected to the contact portion.

8. The heat sink as claimed in claim 1, wherein the heat-dissipating portion comprises at least one groove located on a periphery thereof.

9. A heat sink comprising:
a heat-dissipating portion comprising a plurality of fins and a bottom surface; and
a contact portion disposed on the heat-dissipating portion and connected to a electric device generating heat, wherein the contact portion and the heat-dissipating portion are a single and unitary member, and the contact portion comprises at least one concave disposed on an edge of the contact portion radially.

10. The heat sink as claimed in claim 9, wherein the contact portion comprises an axial cross section increases along a direction away from the heat-dissipating portion.

11. The heat sink as claimed in claim 9, wherein the contact portion comprises a first portion and a second portion, the second portion comprises a top surface and a bottom surface, both of which are respectively connected to the first portion and the heat-dissipating portion, the concave is disposed between the first portion and the second portion or between the first portion and the heat-dissipating portion.

12. The heat sink as claimed in claim 11, wherein an edge of the first portion or an edge of the second portion is inclined.

13. The heat sink as claimed in claim 11, wherein the axial cross section of the first portion or the second portion decreases along a direction away from the heat-dissipating portion, or the axial cross section of the first portion or the second portion increases along a direction away from the heat-dissipating portion.

14. The heat sink as claimed in claim 9, further comprising a through hole passing through the contact portion and extending to the heat-dissipating portion for disposing a thermally conducting element therein.

15. The heat sink as claimed in claim 9, wherein the heat-dissipating portion comprises at least one groove disposed on a periphery of the heat-dissipating portion.

16. A heat sink comprising:
a heat-dissipating portion having a plurality of fins; and
a contact portion disposed on the heat-dissipating portion, wherein the contact portion and the heat-dissipating portion are a single unitary member, and the contact portion comprises at least one concave.

17. The heat sink as claimed in claim 16, wherein the contact portion comprises a first portion and a second portion, the second portion comprises a top surface and a bottom surface, both of which are respectively connected to the first portion and the heat-dissipating portion, the first axial cross section is located on the first portion, and the second axial cross section is located on the second portion.

18. The heat sink as claimed in claim 17, wherein the axial cross section of the first portion or the second portion decreases along a direction away from the heat-dissipating portion, or the axial cross section of the first portion or the second portion increases along a direction away from the heat-dissipating portion.

19. The heat sink as claimed in claim 17, wherein the concave is formed between the first portion and the second portion, and the concave is a profile of V-shaped, polygon, bar-shaped, ring-shaped, or curve.

20. The heat sink as claimed in claim 16, further comprising a through hole and a thermally conducting member, wherein the through passes through the contact portion and extends to the heat-dissipating portion, and the thermally conducting member disposed in the through hole to connect to the contact portion and the electric device.
